(19) United States
(12) Patent Application Publication
(10) Pub. No.: US 2011/0241757 A1
(43) Pub. Date: Oct. 6, 2011

(54) THYRISTOR GATE PULSES IN STATIC VAR COMPENSATOR

(75) Inventor: Lynn Johnson, Verona, WI (US)

(73) Assignee: American Superconductor Corporation, Devens, MA (US)

(21) Appl. No.: 12/749,930

(22) Filed: Mar. 30, 2010

(51) Int. Cl. H03K 17/72

(52) U.S. Cl. 327/440

(57) ABSTRACT

A method of controlling a static VAR compensator includes providing a static VAR compensator having a reactive component and a thyristor for switching the reactive component into and out of a power distribution network; monitoring a periodic waveform on the power distribution network and controlling operation of the thyristor on the basis of the harmonic frequency content of the waveform.

### FIELD OF DISCLOSURE

This disclosure relates to electrical power distribution, and in particular, to controlling the complex power vectors in a power transmission system.

### BACKGROUND

The waveform that exists at all points in a power transmission system is ideally a sinusoid of constant frequency. In the US, that frequency is 60 Hz. However, in many parts of the world, the frequency is 50 Hz.

In practice, the waveform that exists in some parts of the power transmission system is a superposition of a fundamental frequency and various harmonic components. These harmonic components arise from various non-linear loads attached to the power transmission system.

The power transmitted by a power transmission system is represented by a power vector in the complex plane. The imaginary component of the power vector represents reactive power, while the real component represents the power that is actually transmitted. The ratio between the real component of the power vector and the magnitude of the power vector is referred to as a “power factor.”

Although the reactive power is not actually transmitted, it nevertheless results in ohmic losses. As a result, if efficient power transmission is sought, it is best to cause the power vector to be purely real. Expressed differently, to transmit power effectively, it is best to cause the power factor to be as close to unity as possible.

The relative magnitudes of the real and reactive power depend on a phase relationship between the voltage and current waveform on the transmission line. This phase relationship depends on the imaginary part of the impedance (i.e. the reactance) seen by the transmission line. Thus, to control the phase relationship, one controls the reactance.

Control over reactance is carried out by monitoring the angle of the power vector and switching reactive elements in and out of electrical connection with the power transmission system, in an attempt to drive the angle back to zero relative to the positive real axis. Depending on whether one wishes to rotate the power vector clockwise or counter-clockwise, one would switch in a capacitative reactance or an inductive reactance. The device for carrying out this function is a static VAR compensator.

### SUMMARY

In one aspect, the invention features a method of controlling a static VAR compensator. The method includes providing a static VAR compensator having a reactive component and a thyristor for switching the reactive component into and out of a power distribution network; monitoring a periodic waveform on the power distribution network, the waveform including harmonic frequency content; and controlling operation of the thyristor on the basis of the harmonic content of the waveform.

Practices of the invention include those in which controlling operation of the thyristor includes applying a current to a gate of the thyristor when a probability of ringing in a current between an anode of the thyristor and a cathode of the thyristor is in excess of a selected threshold, and those in which controlling operation of the thyristor includes controlling operation on the basis of an estimate of a ratio between a fundamental frequency component of the periodic waveform and the harmonic frequency content.

In one practice, controlling operation of the thyristor includes determining an envelope defined by a superposition of a fundamental frequency component of the periodic waveform and harmonic frequency content of the periodic waveform. Certain of these practices further include, at a first time, turning on current to a gate terminal of the thyristor, the first time being a time at which the envelope reaches a first designated value; and at a second time, turning off current to the gate terminal, the second time being the next time after the first time that the envelope reaches a second designated value.

Other practices include those in which controlling operation of the thyristor includes applying a gate current to the thyristor when the periodic waveform reaches a first designated value, those in which controlling operation of the thyristor includes ceasing application of a gate current to the thyristor when the periodic waveform reaches a second designated value, and those in which controlling operation of the thyristor includes applying a gate current to the thyristor when the periodic waveform reaches a first designated value, and ceasing application of the gate current when the periodic waveform next reaches the designated value, and those in which controlling operation of the thyristor includes causing a gate current to switch between an on-state and an off-state when the periodic waveform reaches a zero crossing.

Other practices of the invention include determining an envelope of the periodic waveform, and controlling operation of the thyristor on the basis of the envelope.

Yet other practices include inspecting a table. In some of these practices, controlling operation of the thyristor includes: determining harmonic frequency content of the periodic waveform, inspecting a table to determine an envelope associated with the harmonic frequency content, and controlling operation of the thyristor on the basis of the envelope.

Other ways of controlling operation of the thyristor are contemplated as being within the scope of this invention. For example, practices of the invention include those in which controlling operation of the thyristor includes applying a gate current to the thyristor at least twice during a period of the periodic waveform; those in which controlling operation of the thyristor includes ceasing application of a gate current to the thyristor at least twice during a period of the periodic waveform; those in which controlling operation of the thyristor includes, on the basis of the periodic waveform, applying gate current during a refractory period of the thyristor, and ceasing application of the gate current during a non-refractory period of the thyristor; those in which controlling operation of the thyristor includes applying gate current symmetrically about time at which the periodic waveform crosses a designated value; and those in which controlling operation of the thyristor includes applying gate current symmetrically about a zero-crossing of the periodic waveform.

In other practices of the invention, controlling operation of the thyristor includes determining a first curve based on a first phase relationship between the harmonic frequency content and a fundamental frequency component of the periodic waveform; and determining a second curve based on a second phase relationship between the harmonic frequency content and the fundamental frequency component, the first and second curve defining an envelope therebetween. Among these practices are those that include applying a gate current to cause a gate pulse that extends from when the first curve crosses a first designated to when the second curve crosses a second designated value.

In another aspect, the invention features a VAR corrector for a power distribution network. The static VAR corrector includes a capacitative reactive load; a thyristor for causing the reactive load to be switched into and out of the power distribution network; a current source for applying a gate current to the thyristor; and a controller for causing gate current to be applied and removed on the basis of harmonic frequency content of a waveform on the network.

In yet another aspect, the invention features a static VAR corrector for a power distribution network. The static VAR corrector includes a capacitative reactive load; a thyristor for causing the reactive load to be switched into and out of the power distribution network; means for applying a gate current to the thyristor; and means for causing gate current to be applied and removed on the basis of a waveform on the network.

These and other features of the invention will be apparent from the following detailed description and the accompanying figures, in which:

### BRIEF DESCRIPTION OF THE FIGURES

FIG. 1 shows a static VAR compensator with a thyristor-switched capacitor;

FIG. 2 shows a static VAR compensator with a thyristor-switched reactor, also known as a thyristor controlled reactor;

FIGS. 3 and 4 show envelopes associated with two levels of harmonic content;

FIG. 5 shows a gate pulse with a duty cycle in excess of 50%;

FIG. 6 shows a gate pulse for a static VAR compensator having a thyristor-switched capacitor;

FIG. 7 shows a controller for a static VAR compensator;

FIG. 8 shows a relationship between harmonic content and gate pulse width; and

FIG. 9 shows a gate pulse for a static VAR compensator having a thyristor-switched reactance.

### DETAILED DESCRIPTION

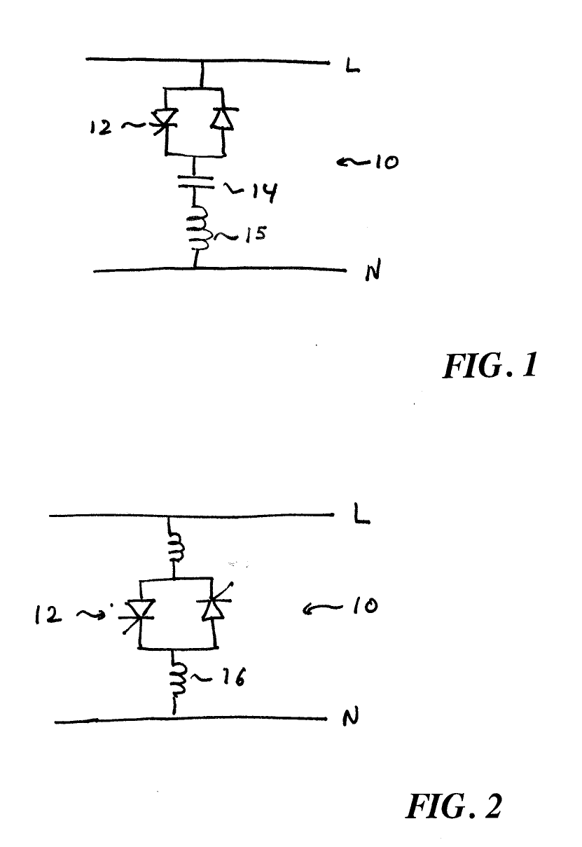

A typical static VAR compensator 10, shown in FIG. 1, brings the power factor to unity by controlling the reactance presented to a power transmission system. Alternatively, a typical static VAR compensator can correct for fast voltage dips and/or flicker. The static VAR compensator 10 typically includes a valve in series with a reactive element. In one embodiment, referred to as a thyristor-switched capacitor configuration and shown in FIG. 1, the valve, which includes a thyristor 12 in parallel with a diode of opposite polarity, switches in a capacitative load 14, which provides a primary impedance, and a detuning inductive reactor 15, which provides a secondary impedance The polarity of the circuit shown in FIG. 1 can be reversed without changing the principles of its operation. In another embodiment, referred to as a thyristor-switched reactance configuration and shown in FIG. 2, the valve, which includes a thyristor 12 in parallel with another thyristor of opposite polarity, switches in an inductive load 16.

The thyristor 12 has three terminals: a gate, a cathode, and an anode. When current is applied to the gate, a conducting path exists between the cathode and the anode. This conducting path exists even if current is taken away from the gate. As a result, the thyristor 12 latches into a conducting state. Once it begins to conduct, it continues to do so without the need to continuously provide gate current.

As a result of the conducting path, current begins to flow between cathode and anode. This places the reactive element in communication with the power transmission system and thereby alters the impedance presented to the system. When the correct reactance is switched into the circuit at the correct time, the power vector rotates toward the positive real axis, thus bringing the power factor closer to unity. Alternatively, switching the correct reactance into the circuit at the correct time can reduce the voltage dip and/or flicker.

The thyristor 12 continues to conduct until the current from anode to cathode drops below a threshold. This threshold is slightly above zero amps, but for most practical purposes, is treated as zero amps. Once this value is reached, the conducting path between anode and cathode disappears. The disappearance of this conducting path in turn disconnects the reactance from the circuit.

As the conducting path disappears, charge carriers (i.e. holes and electrons) still present within the thyristor 12 recombine. The time during which this recombination occurs is the “turn-off time,” or “refractory period.” After the refractory period, it becomes safe to turn the thyristor 12 on again.

During the refractory period, the thyristor 12 is particularly vulnerable to damage. If, during the refractory period, the current between anode and cathode were to somehow rise above the threshold, even momentarily, the conducting path could spontaneously re-open, even when no gate current has been applied. This spontaneous and uncontrolled re-opening of the conducting path between anode and cathode can result in serious physical damage to the thyristor 12.

In operation, one would apply a current pulse to the thyristor gate when the current waveform becomes positive. Then, when the current waveform drops to zero, the thyristor 12 would spontaneously stop conducting. Once the current waveform becomes positive again, one would repeat the cycle.

As mentioned above, the current waveform often includes one or more harmonic components, collectively referred to as “harmonic content,” that arise from non-linear loads. To some extent, these harmonics can be minimized by conventional detuning using the inductive reactor 15 shown in FIG. 1. However, detuning can be difficult and time-consuming.

When harmonic content is superimposed on the fundamental, it is possible for the current to momentarily dip below zero, and to then to rise above zero again in a very short time. This effect, which is hereafter referred to as “ringing,” would most likely occur at around the time the fundamental current waveform crosses the time axis. However, although it is possible to predict when this crossing occurs, it is difficult to predict how far away from this crossing one must be before ringing is unlikely to occur.

As noted above, if, as a result of ringing, current momentarily rises above the threshold during a refractory period, the thyristor may sustain serious damage. Consequently, it is preferable to avoid having a refractory period occur while ringing is likely.

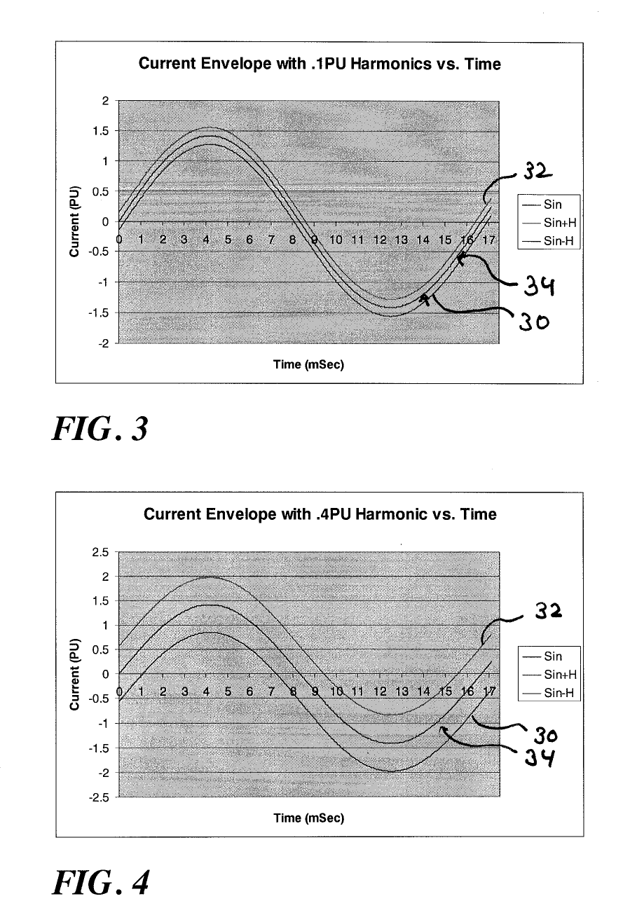

FIGS. 3 and 4 show the uncertainty in the zero-crossing times for two current waveforms having different harmonic content. Each plot shows a lower fundamental waveform 30 and an upper fundamental waveform 32. Together, these waveforms define an envelope 34. These waveforms are obtained by assuming that the harmonic content and the fundamental component are in phase quadrature. The zero-crossing can occur anywhere within that envelope 34. The actual width of the envelope 34, and hence the uncertainty in where the zero-crossing would occur, depends on the harmonic content.

In FIG. 3, which corresponds to 0.1 PU harmonic content, a zero-crossing is possible anywhere between about 8 ms and about 8.6 ms after the beginning of the waveform. As the harmonic content increases, this uncertainty becomes greater. In FIG. 4, which corresponds to a harmonic content of 0.4 PU, a zero-crossing can occur anywhere from about 7.2 ms to about 9.5 ms after the beginning of the waveform. In both cases, the actual time at which a zero-crossing would occur depends on the phase relationships between the harmonics.

Knowing when the zero-crossing will occur is of particular importance in a static VAR compensator 10 because it is around that time that ringing due to harmonics is most likely to occur. As noted above, if ringing occurs when the gate current is off, the conducting path may spontaneously re-open during the refractory period, thus raising the risk of thyristor damage. However, as is apparent from FIGS. 3 and 4, the time of the zero-crossing, and hence the period during which ringing is likely, can be unpredictable.

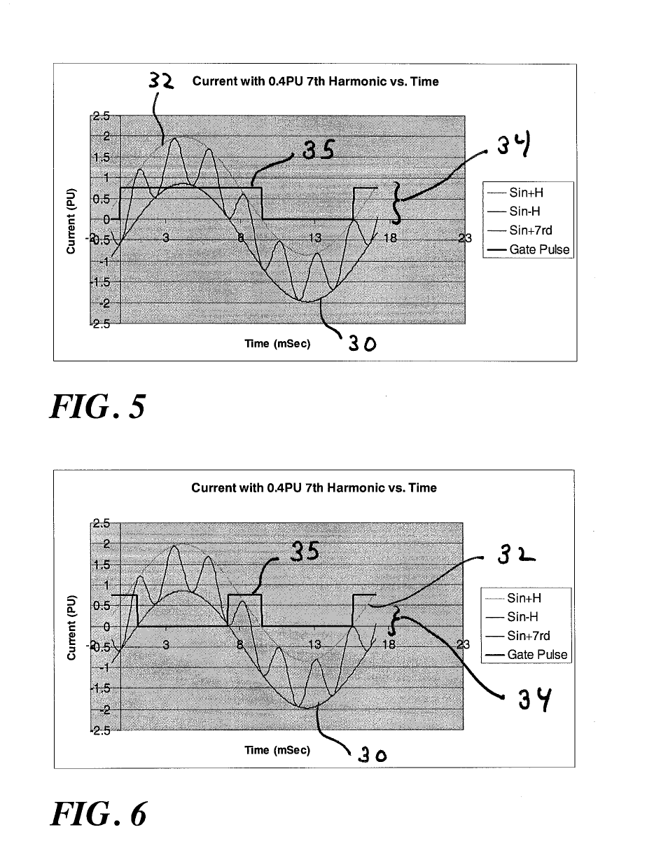

One way to reduce the likelihood of thyristor damage from uncontrolled ringing is to have a pulse of gate current (a “gate pulse” 35) that lasts for at least half a period of the current waveform, as shown in FIG. 5. This ensures that the gate current will still be on, and hence that a refractory period will not occur, during the interval when ringing is likely to occur.

A difficulty with this approach is that it wastes considerable amounts of energy, and generates excessive waste heat. In principle, the gate current is only needed to open a conducting path between anode and cathode, not to maintain it. In fact, one of the advantages of a thyristor 12 is that once on, it stays on until current drops below a threshold, after which it spontaneously turns off. By having to maintain a gate current for well over half a period, one eviscerates a principal advantage of a thyristor 12.

Another disadvantage is that the timing of the gate current is, to a great extent, an educated guess. It is possible for the gate current to be removed even though ringing is still possible. This risk can be reduced by detuning. But as noted above, detuning can be a difficult procedure.

An alternative approach, which avoids the foregoing difficulties, is to apply a gate pulse 35 symmetrically around each zero-crossing, whether the crossing is a positive crossing (i.e. the waveform is transitioning from being negative to being positive) or a negative crossing.

As shown in FIG. 6, the gate pulse 35 begins at the zero-crossing of the lower curve and ends at the zero-crossing of the upper curve. As a result, the interval during which current actually drives the thyristor gate is limited to the width of the envelope 34. A first gate pulse starts at a negative peak voltage and continues until the end of the upper waveform's zero-crossing.

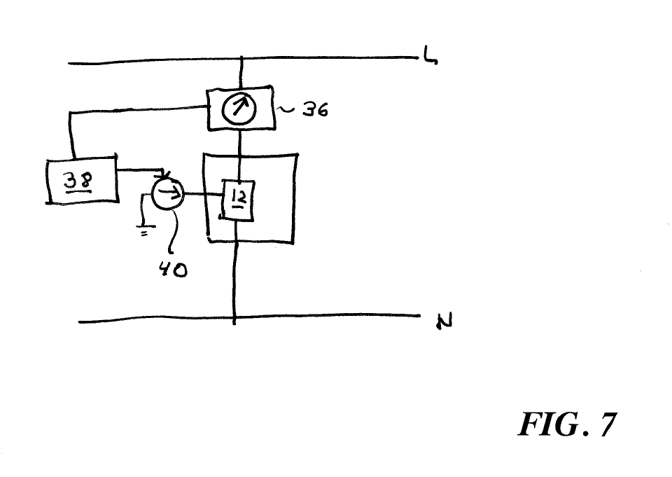

In one embodiment, shown in FIG. 7, a current measuring element 36 measures current through the anode/cathode path of a thyristor 12 and provides a measurement of current to a controller 38. The controller uses that measurement to determine when to drive a current source 40 that is connected to the gate terminal of the thyristor 12.

In some embodiments, the controller 38 determines the harmonic content of the current and adaptively controls when the gate pulse should occur. In other embodiments, the controller 38 observes the waveform and attempts to predict when zero-crossings will occur.

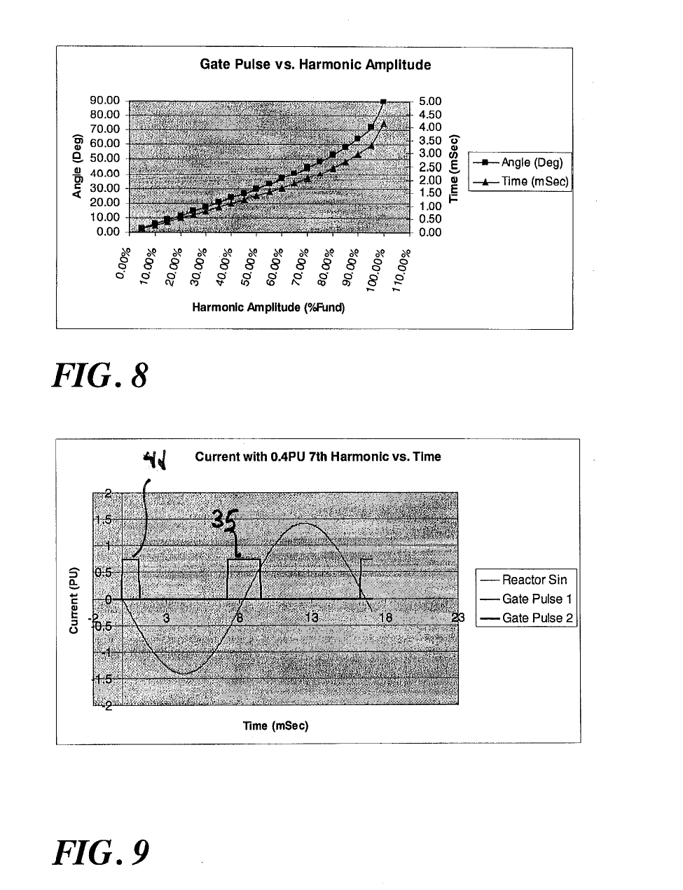

One way to determine how wide the pulse should be based on harmonic content of the current waveform is to use a table corresponding to the graph shown in FIG. 8.

To use the graph shown in FIG. 8, the controller determines the harmonic amplitude of the current waveform and then determines the number of degrees corresponding to that harmonic amplitude using the arcsine of the harmonic current PU amplitude as shown in FIG. 8. The number of degrees indicates the fraction of one 360 degree period that the gate pulse should cover. For convenience, times corresponding to degrees are shown in FIG. 8 for the case of a 60 Hz waveform, such as one would find on a power distribution system.

In FIG. 9, the same gate pulses are used, but they are used to drive alternate thyristors. In addition, the pulse width can be lower than it is in the thyristor-switched capacitor configuration case because the harmonic current is inherently lower, and therefore the envelope 34 is inherently narrower. Another difference is that although the first gate pulse should start on a negative voltage peak to minimize inrush current, there is no need to start with a complete cycle through the gate pulse. As a result, the first gate pulse 41, which arises when the controller is first turned on, is narrower than succeeding gate pulses 35, and begins at a negative voltage peak (i.e. zero current).

The waveforms shown in FIGS. 6 and 9 both feature two rather than one gate pulse per period. The gate pulses are selected to occur when ringing is most probable, to ensure that the thyristor 12 is being driven when ringing occurs. The width of the pulses in both cases depends on the harmonic content of the current waveform. In cases where the harmonic content increases, only the width of the gate pulse need be increased.

While the foregoing discussion has referred to “current waveform,” it will be apparent that current waveform is related to other electrical waveforms, such as voltage and power waveforms, and that the methods described herein can readily be adapted to such waveforms by minor modifications.

Having described the invention, and a preferred embodiment thereof, what we claim as new and secured by Letters Patent is:

1. A method of controlling a static VAR compensator, said method comprising:
providing a static VAR compensator having a reactive component and a thyristor for switching said reactive component into and out of a power distribution network;
monitoring a periodic waveform on said power distribution network, said periodic waveform including harmonic frequency content; and
controlling operation of said thyristor on the basis of said harmonic frequency content of said periodic waveform.

2. The method of claim 1, wherein controlling operation of said thyristor comprises applying a current to a gate of said thyristor when a probability of ringing in a current between an anode of said thyristor and a cathode of said thyristor is in excess of a selected threshold.

3. The method of claim 1,
wherein controlling operation of said thyristor comprises controlling operation on the basis of an estimate of a ratio between a fundamental frequency component of said periodic waveform and said harmonic frequency content.

4. The method of claim 1,
wherein controlling operation of said thyristor comprises determining an envelope defined by a superposition of a fundamental frequency component of said periodic waveform and harmonic frequency content of said periodic waveform.

5. The method of claim 4, wherein controlling operation of said thyristor further comprises:
at a first time, turning on current to a gate terminal of said thyristor, said first time being a time at which said envelope reaches a first designated value; and
at a second time, turning off current to said gate terminal, said second time being the next time after said first time that said envelope reaches a second designated value.

6. The method of claim 1, wherein controlling operation of said thyristor comprises applying a gate current to said thyristor when said periodic waveform reaches a first designated value.

7. The method of claim 1, wherein controlling operation of said thyristor comprises ceasing application of a gate current to said thyristor when said periodic waveform reaches a second designated value.

8. The method of claim 1, wherein controlling operation of said thyristor comprises
applying a gate current to said thyristor when said periodic waveform reaches a first designated value, and
ceasing application of said gate current when said periodic waveform next reaches said designated value.

9. The method of claim 1, wherein controlling operation of said thyristor comprises causing a gate current to switch between an on-state and an off-state when said periodic waveform reaches a zero crossing.

10. The method of claim 1, further comprising determining an envelope of said periodic waveform, and controlling operation of said thyristor on the basis of said envelope.

11. The method of claim 1, wherein controlling operation of said thyristor comprises:
determining harmonic frequency content of said periodic waveform,
inspecting a table to determine an envelope associated with said harmonic frequency content, and
controlling operation of said thyristor on the basis of said envelope.

12. The method of claim 1, wherein controlling operation of said thyristor comprises applying a gate current to said thyristor at least twice during a period of said periodic waveform.

13. The method of claim 1, wherein controlling operation of said thyristor comprises ceasing application of a gate current to said thyristor at least twice during a period of said periodic waveform.

14. The method of claim 1, wherein controlling operation of said thyristor comprises, on the basis of said periodic waveform, applying gate current during a refractory period of said thyristor, and ceasing application of said gate current during a non-refractory period of said thyristor.

15. The method of claim 1, wherein controlling operation of said thyristor comprises applying gate current symmetrically about a time at which said periodic waveform crosses a designated value.

16. The method of claim 1, wherein controlling operation of said thyristor comprises applying gate current symmetrically about a zero-crossing of said periodic waveform.

17. The method of claim 1, wherein controlling operation of said thyristor comprises:
determining a first curve based on a first phase relationship between said harmonic frequency content and a fundamental frequency component of said periodic waveform; and
determining a second curve based on a second phase relationship between said harmonic frequency content and said fundamental frequency component, said first and second curve defining an envelope therebetween.

18. The method of claim 17, further comprising:
applying a gate current to cause a gate pulse that extends from when said first curve crosses a first designated value to when said second curve crosses a second designated value.

19. The method of claim 1, wherein controlling operation of said thyristor comprises applying a first gate pulse at a negative peak voltage, and applying gate pulses subsequent to said first gate pulse on the basis of said harmonic frequency content.

20. A static VAR corrector for a power distribution network, said static VAR corrector comprising:
a capacitative reactive load;
a thyristor for causing said reactive load to be switched into and out of said power distribution network;
a current source for applying a gate current to said thyristor; and
a controller for causing gate current to be applied and removed on the basis of harmonic frequency content of a waveform on said network.

21. A static VAR corrector for a power distribution network, said static VAR corrector comprising:
a capacitative reactive load;
a thyristor for causing said reactive load to be switched into and out of said power distribution network;
means for applying a gate current to said thyristor; and
means for causing gate current to be applied and removed on the basis of a waveform on said network.
